(19) United States
(12) Patent Application Publication
(10) Pub. No.: US 2011/0278708 A1
(43) Pub. Date: Nov. 17, 2011

(54) LEAD FRAME, SEMICONDUCTOR DEVICE, AND METHOD FOR MANUFACTURING SEMICONDUCTOR DEVICE

(75) Inventor: Takahiro Yurino, Yokohama (JP)

(73) Assignee: FUJITSU SEMICONDUCTOR LIMITED, Yokohama-shi (JP)

(21) Appl. No.: 13/034,283

(22) Filed: Feb. 24, 2011

(30) Foreign Application Priority Data
May 11, 2010 (JP) 2010-108869

(51) Int. Cl. H01L 23/495; H01L 21/50

(52) U.S. Cl. 257/676; 438/123

(57) ABSTRACT

A lead frame includes a die stage on which a semiconductor element is mounted, a plurality of connection terminals radially arranged around the die stage, and a plurality of wire connection portions which are each provided at a leading end portion on the die stage side of one of the plurality of connection terminals. Moreover, a fixing tape is attached to back surface sides of the wire connection portions and fixes the plurality of wire connection portions all together. Adjacent two of the wire connection portions are staggered in a longitudinal direction of the corresponding connection terminals, and a portion of the connection terminal running along the wire connection portion of the adjacent connection terminal is formed to be narrower and thinner than the wire connection portion.

### CROSS-REFERENCE TO RELATED APPLICATIONS

This application is based upon and claims and the benefit of priority of the prior Japanese Patent Application No. 2010-108869, filed May 11, 2010, the entire contents of which are incorporated herein by reference.

### FIELD

The embodiments discussed herein are related to a lead frame, a semiconductor device, and a method for manufacturing the semiconductor device.

### BACKGROUND

A quad flat package (QFP) is one type of package of semiconductor device. QFP is a package with a thin plate shape in which a semiconductor element (semiconductor chip) is sealed with resin or the like using a lead frame. In QFP, connection terminals are led out from four sides of the package. In each of the connection terminals, a portion led out from the package is referred to as an outer lead, and a portion inside the package is referred to as an inner lead.

The semiconductor element is mounted on a portion of the lead frame called a die stage. The inner leads are radially arranged around the die stage, and leading end portions of the inner leads are electrically connected to the semiconductor element by wire bonding.

Recently, further integration and improvement in performance of semiconductor devices have been put forward. As a result, the number of connection terminals tends to be increased. To deal with such semiconductor devices, leading end portions of inner leads are each preferably reduced in width (arranged at a smaller pitch). However, if the width of the leading end portions of the inner leads is made too narrow, wire bonding might not be performed. Thus, there is a limitation in reduction of the width of the leading end portions of the inner leads.
Patent Citation 1: Japanese Laid-open Patent Publication No. 07-74304
Patent Citation 2: Japanese Laid-open Patent Publication No. 07-142522
Patent Citation 3: Japanese Laid-open Patent Publication No. 2002-23871

### SUMMARY

According to an aspect, there is provided a lead frame including, a die stage on which a semiconductor element is mounted, a plurality of connection terminals radially arranged around the die stage, a plurality of wire connection portions which are each provided at a leading end portion on the die stage side of one of the plurality of connection terminals and which are each connected to a metal thin wire connecting the wire connection portion to an electrode pad of the semiconductor element, and a fixing tape which is attached to back surface sides of the wire connection portions and fixes the plurality of wire connection portions all together, wherein adjacent two of the wire connection portions are staggered in a longitudinal direction of the corresponding connection terminals, and a portion of the connection terminal running along the wire connection portion of the adjacent connection terminal is formed to be narrower and thinner than the wire connection portion.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a partially cutaway view illustrating an example of a semiconductor device according to a first embodiment;

FIG. 2 is a cross-sectional view of the semiconductor device according the first embodiment;

FIG. 3 is a view illustrating leading end portions of inner leads of connection terminals in an enlarged manner;

FIG. 4A is a cross-sectional view taken along a line I-I of FIG. 3, FIG. 4B is a cross-sectional view taken along a line II-II of FIG. 3, FIG. 4C is a cross-sectional view taken along a line III-III of FIG. 3, and FIG. 4D is a cross-sectional view taken along a line IV-IV of FIG. 3;

FIGS. 5A to 5D are views (part 1) illustrating a method for manufacturing a lead frame and the semiconductor device according to the first embodiment;

FIG. 6 is view (part 2) illustrating the method for manufacturing the lead frame and the semiconductor device according to the first embodiment;

FIG. 7 is view (part 3) illustrating the method for manufacturing the lead frame and the semiconductor device according to the first embodiment;

FIG. 8 is view (part 4) illustrating the method for manufacturing the lead frame and the semiconductor device according to the first embodiment;

FIG. 9 is view (part 5) illustrating the method for manufacturing the lead frame and the semiconductor device according to the first embodiment;

FIG. 10 is view (part 6) illustrating the method for manufacturing the lead frame and the semiconductor device according to the first embodiment;

FIG. 11 is a view illustrating leading end portions of inner leads of a lead frame of a semiconductor device according to a second embodiment in an enlarged manner;

FIG. 12A is a cross-sectional view taken along a line V-V of FIG. 11, FIG. 12B is a cross-sectional view taken along a line VI-VI of FIG. 11, FIG. 12C is a cross-sectional view taken along a line VII-VII of FIG. 11, and FIG. 12D is a cross-sectional view taken along a line VIII-VIII of FIG. 11;

FIG. 13(A) and FIG. 13(B) are cross-sectional views illustrating an example of a mask shape in manufacturing of the lead frame according to the second embodiment;

FIG. 14 is a view illustrating leading end portions of inner leads of a lead frame of a semiconductor device according to a third embodiment in an enlarged manner;

FIG. 15A is a cross-sectional view taken along a line IX-IX of FIG. 14, FIG. 15B is a cross-sectional view taken along a line X-X of FIG. 14, FIG. 15C is a cross-sectional view taken along a line XI-XI of FIG. 14, and FIG. 15D is a cross-sectional view taken along a line XII-XII of FIG. 14;

FIG. 16 is a schematic view illustrating where an opening portion of a mask is located when metal plating is applied to leading end portions of inner leads;

FIG. 17 is a cross-sectional view illustrating a step of removing a plating film attached to portions in front and rear of wire connection portions in a method for manufacturing a semiconductor device according to the third embodiment; and

FIG. 18 is a plan view illustrating part of a lead frame according to another embodiment.

### DESCRIPTION OF EMBODIMENTS

Embodiments will be described below with reference to the attached drawings.

### First Embodiment

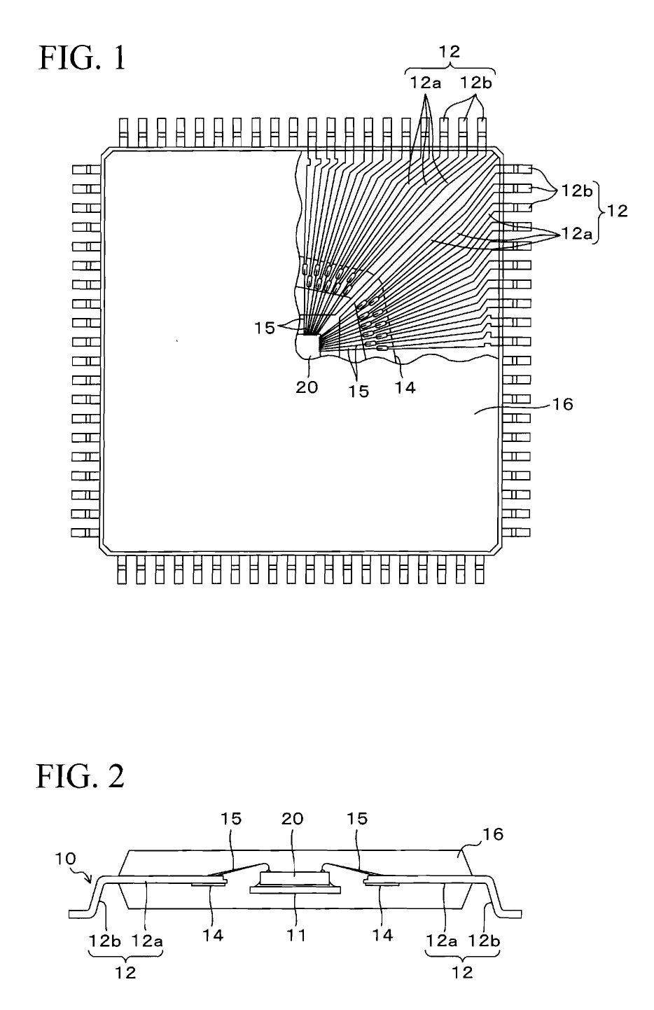

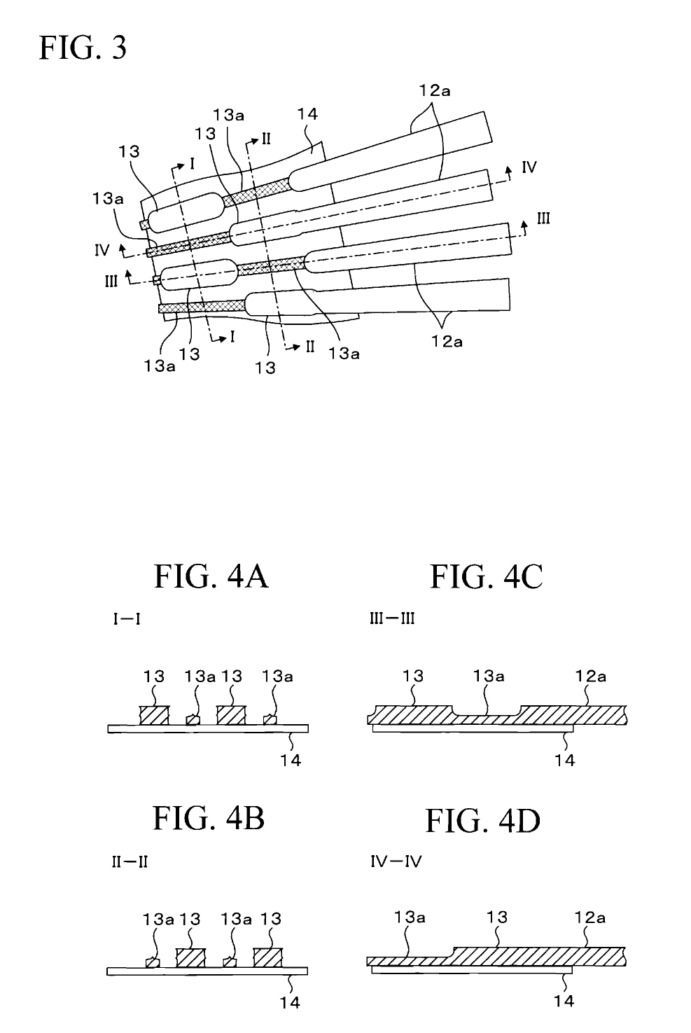

FIG. 1 is a partially cutaway view illustrating an example of a semiconductor device according to a first embodiment, and likewise, FIG. 2 is a cross-sectional view of the semiconductor device. In addition, FIG. 3 is a view illustrating leading end portions of inner leads of connection terminals in an enlarged manner. FIG. 4A is a cross-sectional view taken along a line I-I of FIG. 3, FIG. 4B is a cross-sectional view taken along a line II-II of FIG. 3, FIG. 4C is a cross-sectional view taken along a line III-III of FIG. 3, and FIG. 4D is a cross-sectional view taken along a line IV-IV of FIG. 3.

A lead frame 10 is formed of a metal thin plate made of copper alloy or the like, and includes a die stage 11 and connection terminals 12. A semiconductor element (semiconductor chip) 20 is bonded onto the die stage 11 with electrically conductive adhesive (die bond) such as Ag (silver) paste. As illustrated in FIG. 1, the multiple connection terminals 12 (inner leads 12a) are radially arranged around the die stage 11.

Electrode pads (not illustrated) provided in the semiconductor element 20 and the connection terminals 12 are electrically connected to each other by metal thin wires 15 which are formed by wire bonding. Then, the semiconductor element 20, the die stage 11, the metal thin wires 15 and inner leads 12a are sealed by sealing resin 16 in a way that outer leads 12b are led out to the outside of the sealing resin 16. Each of the outer leads 12b is bent into a crank shape, and a tip portion thereof is soldered to a printed wiring board or the like.

The lead frame of this embodiment will be described below in further detail.

In a leading end portion on the die stage 11 side of each of the connection terminals 12 (inner leads 12a), a wire connection portion 13 is provided as illustrated in FIG. 3. The metal thin wire 15 is to be connected to this wire connection portion 13. The wire connection portion 13 is formed to be wider than portions in front and rear (front and rear in the longitudinal direction of the connection terminal 12: illustrated as shaded portions in FIG. 3) thereof, and its surface is plated with Ag.

In this embodiment, the wire connection portions 13 of adjacent two of the connection terminals 12 are staggered in the longitudinal direction of the connection terminals 12. In other words, the wire connection portions 13 are arranged in a zigzag. The lead frame with this arrangement is usable in a higher pin count semiconductor device while securing a width needed for wire bonding.

Furthermore in this embodiment, as illustrated in the cross-sectional views of FIG. 4A to 4D, a portion of the connection terminal 12 is narrow and thin, the portion running along the wire connection portion 13 of the adjacent connection terminal 12. Hereafter, the narrow portion of the connection terminal 12 running along the wire connection portion 13 of the adjacent connection terminal 12 will be referred to as a narrow portion 13a.

In the lead frame according to this embodiment, the leading end portions of the connection terminals 12 are arranged at a narrow pitch. If the width of the portion (narrow portion 13a) of the connection terminal 12 running along the wire connection portion 13 of the adjacent connection terminal 12 is equal to or larger than the width of the wire connection portion 13, the connection terminals 12 may not be arranged at a narrow pitch. Moreover, if the thickness of the narrow portion 13a is equal to the thickness of the wire connection portion 13, short circuit may occur between the adjacent two connection terminals 12 due to variation in etching condition during formation of the lead frame.

Thus, in this embodiment, the portion (narrow portion 13a) of the connection terminal 12 running along the wire connection portion 13 of the adjacent connection terminal 12 is narrow and thin as described above.

Furthermore, in this embodiment, back surface sides of the leading end portions (wire connection portions 13 and their periphery) of the connection terminals 12 are bonded to a fixing tape 14. Since the leading end portions of the connection terminals 12 are each formed to be narrow, the leading end portions easily deform or break only by applying thereto a small stress during manufacturing steps. In this embodiment, however, the leading end portions of the connection terminals 12 are fixed all together by attaching the fixing tape 14 on the lower surface sides of the leading end portions of the connection terminals 12. Thus, the leading end portions of the connection terminals 12 are protected, and the deformation and breakage of the leading end portions of the connection terminals 12 are prevented. For example, a polyimide film or any other insulating resin film which has an adhesive layer on one surface may be used as the fixing tape 14.

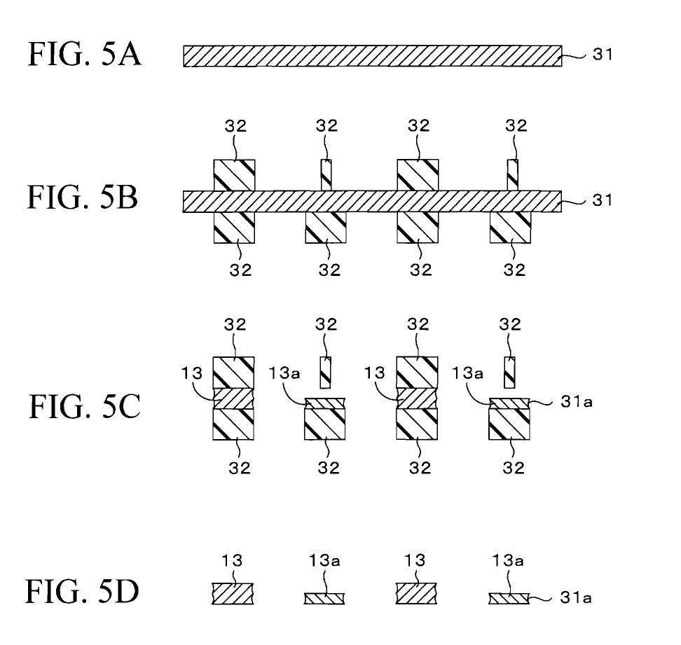

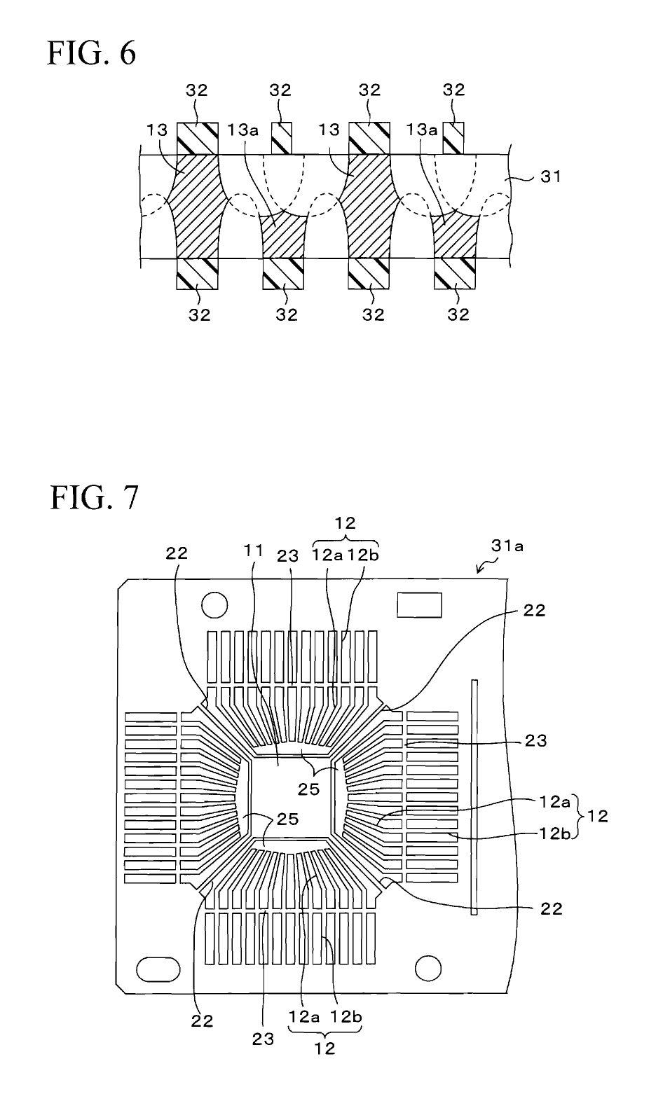

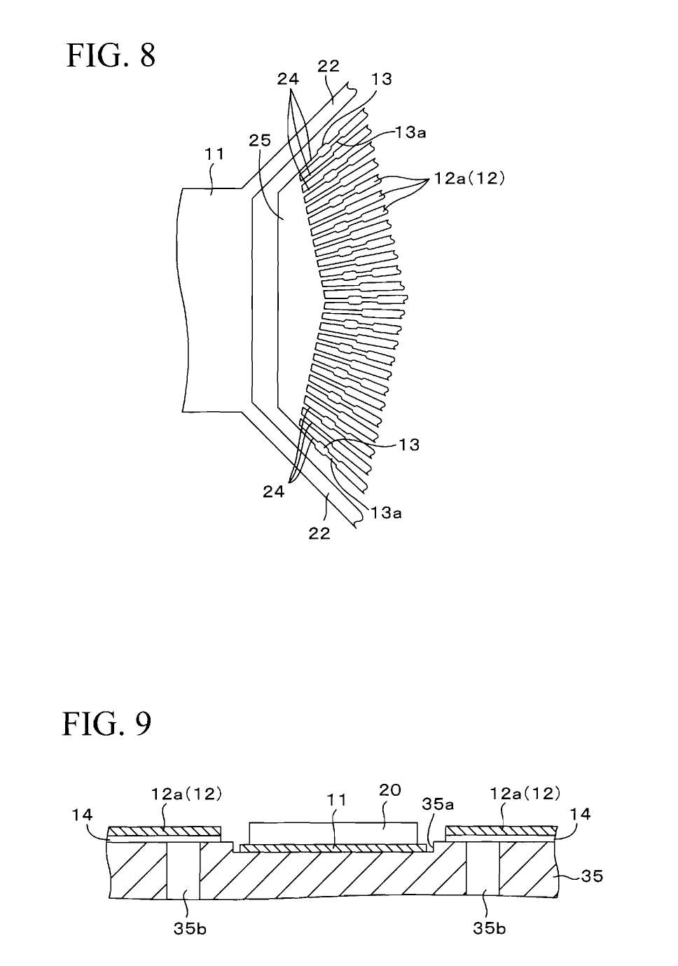

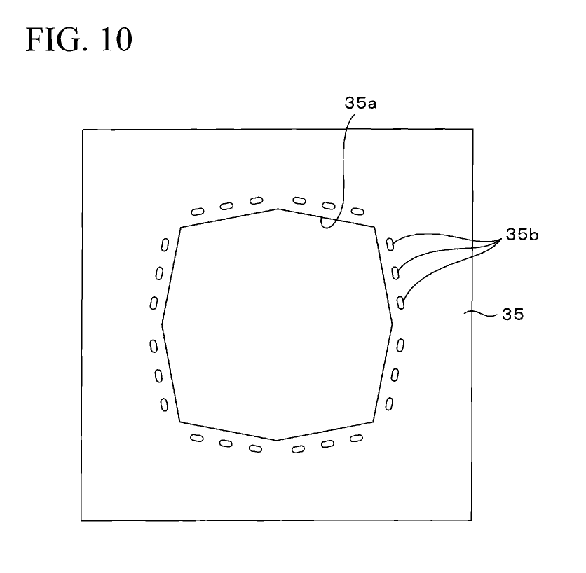

A method for manufacturing the lead frame and the semiconductor device according this embodiment will be described below with reference to FIGS. 5A to 10. Note that, FIGS. 5A to 5D each illustrate a cross section at a position corresponding to the line I-I of FIG. 3. FIG. 6 is a schematic view illustrating an etching step. FIG. 7 is a schematic plan view of the lead frame. FIG. 8 is a view illustrating the leading end portions on the die stage 11 side of the connection terminals 12 (inner lead 12a) in FIG. 7 in an enlarged manner. FIG. 9 is a schematic view illustrating a wire bonding step. FIG. 10 is a plan view illustrating a heating table of a wire bonding apparatus.

Firstly, as illustrated in FIG. 5A, a metal thin plate 31 to be the lead frame is prepared. The metal thin plate 31 is made of, for example, copper alloy in which a small amount of Zn (zinc), P (phosphorus), Cr (chrome) or the like is added to copper. Here, the thickness of the metal thin plate 31 is 0.125 mm.

Next, as illustrated in FIG. 5B, masks (etching masks) 32 each having a predetermined pattern are formed on both surfaces of the metal thin plate 31, respectively, by using photoresist. However, portions of the mask 32 on the upper surface side are each formed to be narrow, the portions of the mask 32 being formed on portions (portions to be the narrow portions 13a and auxiliary bars 24 described below) of the connection terminals 12 in front and rear of the wire connection portions 13. Note that, the mask 32 is not always formed on the narrow portion 13a and the auxiliary bars 24, and may not be formed thereon depending on the thickness of the metal thin plate 31, the widths of the wire connection portions 13 and the narrow portions 13a, the etching condition, and the like.

Thereafter, the metal thin plate 31 with the masks 32 adhered thereto is immersed into an etchant. Thus, the etching progresses from both surface sides of the metal thin plate 31 as illustrated in broken lines of FIG. 6. Hence, a lead frame 31a patterned into a shape as illustrated in FIG. 7 is obtained.

In the lead frame 31a, four corner portions of the die stage 11 are connected to a frame portion of the lead frame 31a by support bars 22. Moreover, the connection terminals 12 are connected to each other at portions in the outer leads 12b by tie bars 23. Furthermore, as illustrated in FIG. 8, each of the leading end portions of the connection terminals 12 (inner leads 12a) is connected to a common connection portion 25 through the auxiliary bar 24 formed at an extension of the corresponding narrow portion 13a. In this embodiment, the common connection portion 25 is provided in each of areas corresponding to four sides of the die stage 11, and each leading end portion of the connection terminal 12 is connected to one of the four common connection portions 25.

In this etching step, the etching progresses only from the upper surface side in portions to be the narrow portions 13a and the auxiliary bars 24. Thus, as illustrated in FIG. 5C, the thicknesses of the narrow portions 13a and the auxiliary bars 24 become smaller than the thicknesses of other portions. After the etching is completed, the masks 32 are removed as illustrated in FIG. 5D.

Note that, in the lead frame 31a, multiple patterns same as the pattern illustrated in FIG. 7 are formed in the longitudinal direction of the lead frame 31a at a constant pitch. Furthermore, although the patterning of the metal thin plate 31 and the reduction of the thicknesses of the narrow portions 13a and the auxiliary bars 24 are performed in the single etching step in the above example, the patterning of the metal thin plate 31 and the reduction of the thicknesses of the narrow portions 13a and the auxiliary bars 24 may be performed separately in different steps. In such case, the thicknesses of the narrow portions 13a and the auxiliary bars 24 may be set to a desired value.

Next, after the wire connection portions 13 are plated with Ag, the fixing tape 14 is attached to the lower surface sides of the leading end portions on the die stage 11 side of the connection terminals 12 (see FIG. 3). Thereafter, portions of the auxiliary bars 24 are cut and the common connection portions 25 are removed. Note that, although the wire connection portions 13 are plated with Ag in this embodiment, the wire connection portions 13 may be plated with Au (gold) or any other metal.

Next, the support bars 22 are bent by a pressing machine to form a step between the die stage 11 and each of the connection terminals 12 (see FIG. 2). Thereafter, the semiconductor element 20 is bonded onto the die stage 11 by the electrically conductive adhesive such as Ag paste. Then, the wire bonding is performed by connecting the electrode pads of the semiconductor element 20 to the wire connection portions 13 of the connection terminals 12 with the metal thin wires 15, respectively. Thus, the connection terminals 12 are electrically connected to the semiconductor element 20.

In the wire bonding step, the lead frame 31a on which the semiconductor element 20 is mounted is placed on the heating table 35 of the wire bonding apparatus as illustrated in FIG. 9. The heating table used in this embodiment has a recess portion 35a at a position corresponding to the die stage 11, and holes 35b at positions corresponding to the leading end portions of the connection terminals 12 as illustrated in FIGS. 9 and 10, the holes 35b being connected to a vacuum pump. Moreover, a heater (not illustrated) is provided in the heating table 35 and is thus capable of heating the lead frame 31a to a predetermined temperature.

The wire bonding with the metal thin wires is performed while heating the die stage 11 and the wire connection portions 13 to, for example, 200° C. with the heating table 35. At this time, the fixing tape 14 is vacuum suctioned through the holes 35b, and thus the leading end portions of the inner leads 12a (connection terminals 12) are fixed to the heating table 35. Hence, the positions of the wire connection portions 13 are not displaced during the wire bonding, and the metal thin wires may be bonded to the wire connection portions 13, respectively.

Next, the semiconductor element 20 is sealed with resin by a transfer molding apparatus, and formed into a semiconductor package. Thereafter, the semiconductor package is removed from the frame of the lead frame 31a. Then, the outer leads 12b led out to the outside of the package are plated with tin or a bismuth-tin alloy (lead free solder) or the like. Subsequently, the outer leads 12b are bent into a predetermined shape, and the tie bars 23 are cut off. Thus, the semiconductor device according to this embodiment is completed. Note that, in FIG. 1, portions of the lead frame 31a which are used in the semiconductor package are illustrated as the lead frame

As described above, in the lead frame used in this embodiment, the wire connection portion 13 is formed to be wider than the portions in front and rear thereof in the leading end portion of each of the connection terminals 12, as illustrated in FIG. 3 and FIGS. 4A to 4D, and the wire connection portions 13 are arranged in a zigzag. This configuration allows many wire connection portions 13 to be arranged in a small region, and thus may be used in a higher pin count semiconductor device.

Moreover, in the lead frame used in this embodiment, the portion (narrow portion 13a) of the connection terminal 12 running along the adjacent wire connection portion 13 is narrow and thin. This configuration may prevent short circuit between the connection terminals 12 due to variation in the etching condition during the etching of the metal thin plate 31 and thus brings about an effect to improve yield.

Furthermore, since the fixing tape 14 is attached to the back surface sides of the leading end portions of the connection terminals 12 in the lead frame used in this embodiment, deformation and breakage of the leading end portions of the connection terminals 12 may be prevented.

This embodiment has described a case where the metal thin plate 31 is patterned using the photolithography method and the etching method to form the lead frame 31a. However, the metal thin plate 31 may be patterned using a press apparatus (punching apparatus) to form the lead frame 31a.

### Second Embodiment

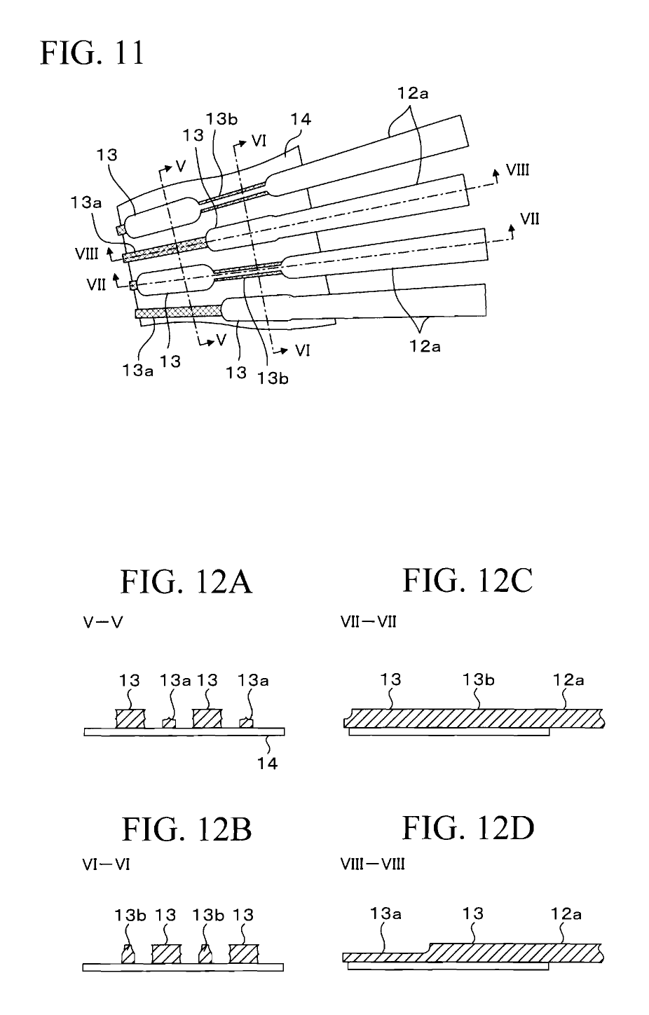

FIG. 11 is a view illustrating leading end portions of inner leads of a lead frame of a semiconductor device according to a second embodiment in an enlarged manner. In addition, FIG. 12A is a cross-sectional view taken along a line V-V of FIG. 11, FIG. 12B is a cross-sectional view taken along a line VI-VI of FIG. 11, FIG. 12C is a cross-sectional view taken along a line VII-VII of FIG. 11, and FIG. 12D is a cross-sectional view taken along a line VIII-VIII of FIG. 11. This embodiment is different from the first embodiment in shape of the leading end portions of the inner leads. Other structures are basically the same as those of the first embodiment, and thus the overlapping descriptions are omitted.

In the first embodiment, as illustrated in FIG. 3 and FIGS. 4A to 4D, the wire connection portions 13 arranged close to the die stage 11 among the wire connection portions 13 are connected to the main body portions of the inner leads 12a through the narrow portions 13a with the small thickness, respectively. Accordingly, it is conceivable that the resistance increases due to these narrow portions 13a.

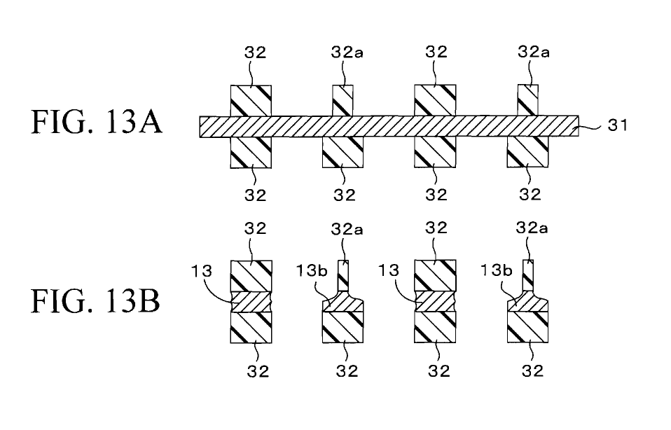

Alternatively, in this embodiment, a protruding portion is provided in the width-direction center portion of each of narrow portions 13b which connects the wire connection portion 13 close to the die stage 11 and the main body portion of the inner lead 12a as illustrated in FIG. 11 and FIGS. 12A to 12D. In other words, as illustrated in FIG. 13A, when the metal thin plate 31 is etched into the lead frame 31a, mask 32a slightly narrower than the mask 32 on the lower surface side is formed on each of portions to be the narrow portions 13b. Thus, as illustrated in FIG. 13B, metal remains below the masks 32a even after the etching is completed.

Provision of the protruding portions as described above causes the thickness of the narrow portion 13b to be the same as the thicknesses of the wire connection portion 13 and the main body portion of the inner lead 12a. Thus, the cross-section area of the narrow portion 13b is made larger than the cross-section area of the narrow portion 13a. Thus, the resistance value of the narrow portion 13b is reduced, and the electrical characteristic is improved.

### Third Embodiment

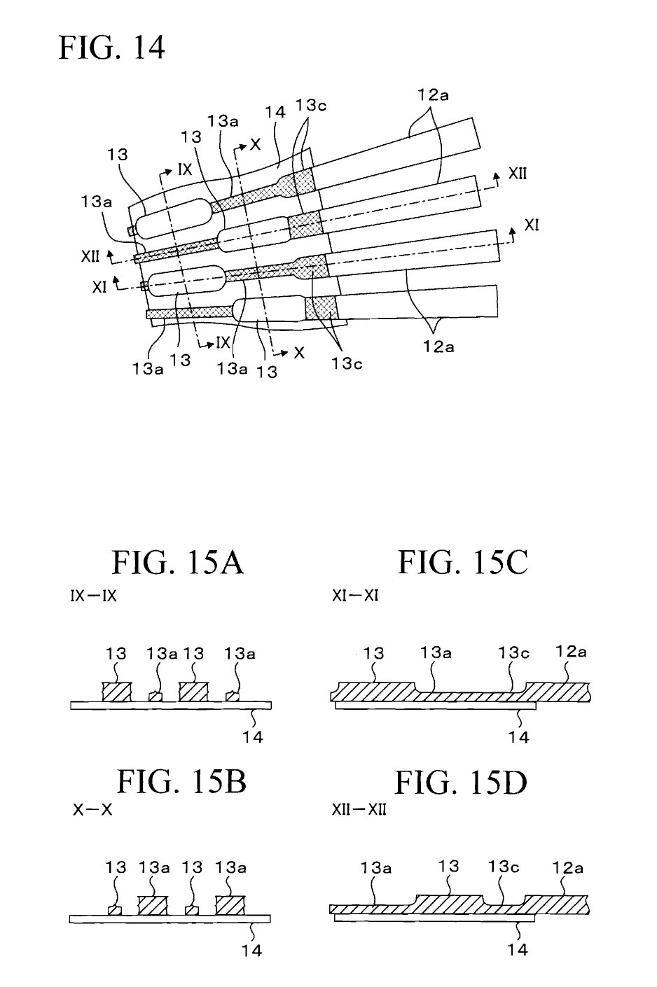

FIG. 14 is a view illustrating leading end portions of inner leads of a lead frame of a semiconductor device according to a third embodiment in an enlarged manner. In addition, FIG. 15A is a cross-sectional view taken along a line IX-IX of FIG. 14, FIG. 15B is a cross-sectional view taken along a line X-X of FIG. 14, FIG. 15C is a cross-sectional view taken along a line XI-XI of FIG. 14, and FIG. 15D is a cross-sectional view taken along a line XII-XII of FIG. 14. This embodiment is different from the first embodiment in shape of the leading end portions of the inner leads. Other structures are basically the same as those of the first embodiment, and thus the overlapping descriptions are omitted.

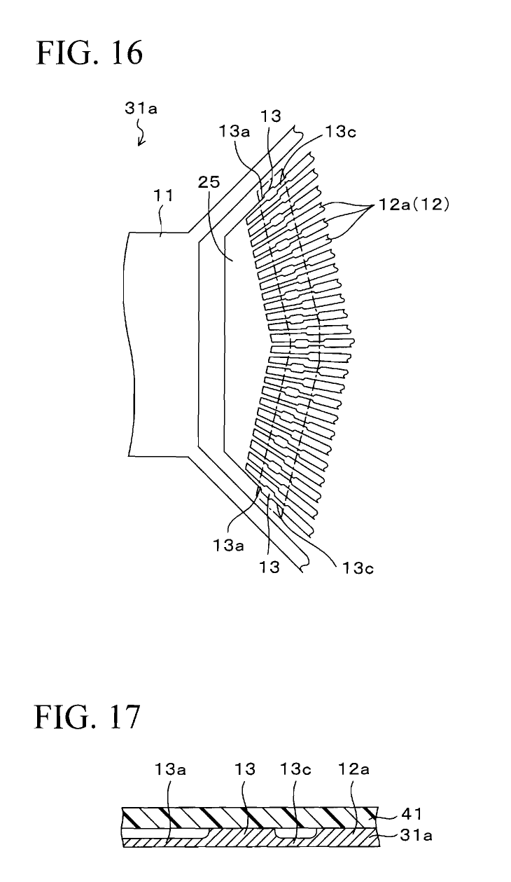

In the first embodiment, the wire connection portions 13 are plated with a metal such as Ag in order to improve the connection in the wire bonding between the metal thin wires and the wire connection portions 13. In this case, portions other than the portions to be plated are covered with plating mask. However, it is difficult to apply metal plating only on the wire connection portions 13, and a plating film adheres also onto the portions (narrow portions 13a and the main body portions of the inner leads 12a) in front and rear of the wire connection portions 13. FIG. 16 illustrates where an opening portion of the plating mask is located, and the metal plating film adheres onto the lead frame 31a in a region surrounded by a dot-dashed line in the drawing. However, since there is a case where adhesion between the metal plating film and the sealing resin is not sufficient, it is preferable to remove the metal plating film in portions other than the wire connection portions 13.

In this embodiment, as illustrated in FIG. 14 and FIGS. 15A to 15D, a thin portion 13c having a thickness smaller than those of the wire connection portion 13 and the main body portion of the inner lead 12a is provided between the wire connection portion 13 and the main body portion of the corresponding inner lead 12a, or between the narrow portion 13a and the main body portion of the corresponding inner lead 12a. Then, the wire connection portions 13 and the portions (narrow portions 13a and thin potions 13c) in front and rear thereof are plated with a metal such as Ag to form the plating film. Thereafter, for example, the wire connection portions 13 side of the lead frame 31a is masked with a hard silicone rubber plate 41 as illustrated in FIG. 17, and the lead frame 31a is immersed into a plating remover. Thus, the plating film adhering to the portions (narrow portions 13a and thin portions 13c) other than the wire connection portions 13 may be removed, and the adhesion between the lead frame and the sealing resin is improved.

### Other Embodiment

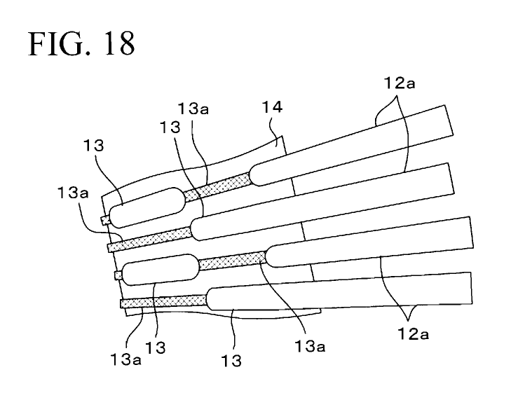

In the first to third embodiments, the width of each of connection portions between the wire connection portions 13 and the main body portions of the inner leads 12a is set to be small. However, as illustrated in FIG. 18, in each of the inner leads 12a with the wire connection portion 13 arranged on the far side from the die stage 11, the width of the connection portion between the wire connection portion 13 and the main body portion of the inner lead 12a may not be made small.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A lead frame comprising:
a die stage on which a semiconductor element is mounted;
a plurality of connection terminals radially arranged around the die stage;
a plurality of wire connection portions which are each provided at a leading end portion on the die stage side of one of the plurality of connection terminals and which are each connected to a metal thin wire connecting the wire connection portion to an electrode pad of the semiconductor element; and
a fixing tape which is attached to back surface sides of the wire connection portions and fixes the plurality of wire connection portions all together, wherein
adjacent two of the wire connection portions are staggered in a longitudinal direction of the corresponding connection terminals, and
a portion of the connection terminal running along the wire connection portion of the adjacent connection terminal is formed to be narrower and thinner than the wire connection portion.

2. The lead frame according to claim 1, wherein a portion of the connection terminal located on an inner lead base side is formed to be narrower than the wire connection portion, and the width of the portion on a front surface side is smaller than the width of the portion on a back surface side.

3. The lead frame according to claim 1, wherein surfaces of the wire connection portions are plated with metal.

4. The lead frame according to claim 1, wherein the die stage, the connection terminals, and the wire connection portions are made of copper alloy.

5. A semiconductor device comprising:
a lead frame;
a semiconductor element disposed on the lead frame;
metal thin wires electrically connecting the lead frame and the semiconductor element; and
a sealing resin sealing the semiconductor element and the metal thin wires, wherein
the lead frame includes:
a die stage on which the semiconductor element is mounted;
a plurality of connection terminals which are radially arranged around the die stage and each of which has a portion led out of the sealing resin;
a plurality of wire connection portions which are each provided at a leading end portion on the die stage side of one of the plurality of connection terminals and which are each connected to a metal thin wire connecting the wire connection portion to an electrode pad of the semiconductor element; and
a fixing tape which is attached to back surface sides of the wire connection portions and fixes the plurality of wire connection portions all together, wherein
adjacent two of the wire connection portions are staggered in a longitudinal direction of the corresponding connection terminals, and
a portion of the connection terminal running along the wire connection portion of the adjacent connection terminal is formed to be narrower and thinner than the wire connection portion.

6. A method for manufacturing a semiconductor device comprising:
forming a lead frame by forming an etching mask on both surfaces of a metal plate and then etching the metal plate from both surface sides;
mounting a semiconductor element on the lead frame;
electrically connecting the semiconductor element and the lead frame with metal thin wires; and
sealing the semiconductor element with resin, wherein
the lead frame includes:
a die stage on which the semiconductor element is mounted;
a plurality of connection terminals which are radially arranged around the die stage and each of which has a portion led out of the sealing resin;
a plurality of wire connection portions which are each provided at a leading end portion on the die stage side of one of the plurality of connection terminals and which are each connected to a metal thin wire connecting the wire connection portion to an electrode pad of the semiconductor element; and
a fixing tape which is attached to back surface sides of the wire connection portions and fixes the plurality of wire connection portions all together, wherein
adjacent two of the wire connection portions are staggered in a longitudinal direction of the corresponding connection terminals, and
a portion of the connection terminal running along the wire connection portion of the adjacent connection terminal is formed to be narrower and thinner than the wire connection portion.

7. The method for manufacturing the semiconductor device according to claim 6, wherein, in the connecting the semiconductor element and the lead frame with the metal thin wires, a portion of the fixing tape is vacuum suctioned so as to be fixed on a heating table of a wire bonding apparatus.

8. The method for manufacturing the semiconductor device according to claim 6, further comprising:
plating the wire connection portions and peripheries thereof of the lead frame with a metal to form a plating film; and
removing the plating film attached to a portion other than the wire connection portions by masking the wire connection portions of the lead frame and then immersing the lead frame into a plating remover.
